(19) United States
(12) Patent Application Publication
(10) Pub. No.: US 2025/0183059 A1
(43) Pub. Date: Jun. 5, 2025

(54) SUBSTRATE PROCESSING APPARATUS

(71) Applicant: ACM RESEARCH (SHANGHAI), INC., Shanghai (CN)

(72) Inventors: Hui Wang, Shanghai (CN); Yang Liu, Shanghai (CN); Xideng He, Shanghai (CN); Haibo Hu, Shanghai (CN); Xiaoyan Zhang, Shanghai (CN); Fuping Chen, Shanghai (CN)

(73) Assignee: ACM RESEARCH (SHANGHAI), INC., Shanghai (CN)

(21) Appl. No.: 18/879,191

(22) PCT Filed: May 19, 2023
(86) PCT No.: PCT/CN2023/095239

§ 371 Date: Dec. 26, 2024

(30) Foreign Application Priority Data
Jun. 23, 2022 (CN) 202210724206.3

(51) Int. Cl. H01L 21/67; B08B 6/00

(52) U.S. Cl. CPC H01L 21/6704; B08B 6/00

(57) ABSTRACT

A substrate processing apparatus, comprising a chamber (1000), a substrate tray (400), a megasonic emission device (30) and a cleaning device (10). The substrate tray (400) is set in the chamber (1000), and it is used to carry a substrate (500). The megasonic emission device (30) is used to transfer megasonic energy to the chemical solution between the megasonic emission device (30) and the substrate (500). The cleaning device (10) is used to clean the megasonic emission device (30), which includes an electrostatic conductor assembly (200), and the conductor assembly (200) is disposed in the cleaning device (10) and is used for electrically connecting with the megasonic emission device (30), so as to conduct the charges away from the megasonic emission device (30), thereby preventing damaging defects on the surface of the substrate (500) due to discharge of the charges accumulated on the megasonic emission device (30).

### FIELD OF THE INVENTION

The present invention relates to the field of semiconductor equipment, and more particularly to a substrate processing apparatus.

### BACKGROUND

SAPS (Space Alternative Phase Shift) Megasonic technology uses high-frequency (0.8 to 1.0 MHZ) alternating current to excite a piezoelectric resonator crystal to generate megasonic wave, which creates a thin acoustic boundary layer near a surface of a substrate and creates a pressure vibration in solution as well as high energy at ultra-high frequencies for effective particle removal.

The core component of SAPS Megasonic technology is a megasonic emission device, which includes a piezoelectric transducer and an acoustic resonator. In a substrate cleaning process, chemical solution is sprayed onto the substrate surface. The megasonic emission device is located above the substrate surface and is lowered and immersed into the chemical solution. The piezoelectric transducer vibrates when energized, and the acoustic resonator transmits high frequency acoustic energy into the chemical solution. The high frequency acoustic energy induces cavitation oscillation to loosen impurity particles on the surface of the substrate to remove contaminants on the surface of the substrate. At this time, as shown in FIG. 35, the megasonic emission device forms a parallel capacitor with the chemical solution 50′ and the substrate 40′, wherein the Al₂O₃ sapphire 302′ in the megasonic emission device is an insulator, and the piezoelectric transducer can be regarded as an upper electrode 301′. The upper electrode 301′ is connected to a radio-frequency power supply 303′, and there is a resistance between the upper electrode 301′ and the radio-frequency power supply 303′, and the chemical solution 50′ and the substrate 40′ can be regarded as a lower electrode. After the substrate cleaning process is completed, the megasonic emission device is turned off, the capacitor starts to discharge. The charges of the upper electrode 301′ move to the resistor (not shown in the figure), and the charges of the lower electrode flow to a substrate tray holding the substrate 40′ (not shown in the figure). However, at this time, the radio-frequency power supply 303′ is disconnected, and the charges at the upper electrode 301′ cannot be completely discharged and accumulate at the upper electrode 301′, resulting in a gradual buildup of residual charges on the megasonic emission device.

When a certain number of residual charges are accumulated on the megasonic emission device, the residual charges will generate a discharge phenomenon on the surface of the substrate 40′ (as shown in FIG. 36), resulting in damage defects on the surface of the substrate 40′.

### SUMMARY

The purpose of the present invention is to solve the problem of damage to the surface of the substrate caused by the residual charges accumulated on the megasonic emission device in the prior art. Accordingly, the present invention provides a substrate processing apparatus which has the advantages of eliminating the charges accumulated on the megasonic emission device and preventing damage to the surface of the substrate caused by the discharge of the residual charges on the megasonic emission device.

In order to solve the above problems, one embodiment of the present invention provides a substrate processing apparatus, comprising:

a chamber;

a substrate tray, provided within the chamber, for carrying a substrate;

a megasonic emission device, for transmitting megasonic energy to the chemical solution between the megasonic emission device and the substrate;

a cleaning device, for cleaning the megasonic emission device, the cleaning device comprising an electrostatic conductor assembly provided in the cleaning device and provided for electrically connecting with the megasonic emission device for conducting the charges away from the megasonic emission device.

Another embodiment of the present invention provides a substrate processing apparatus, comprising:

a chamber;

a substrate tray, for carrying a substrate;

a megasonic emission device, the megasonic emission device and the substrate tray being disposed in the chamber, the megasonic emission device being configured for transmitting megasonic energy to the chemical solution between the megasonic emission device and the substrate;

a grounded electric conductor, configured such that when the megasonic emission device is located above the substrate, the charges on the megasonic emission device are conducted to the electric conductor through the chemical solution on the upper surface of the substrate and are conducted away by the electric conductor.

Another embodiment of the present invention provides a substrate processing apparatus, comprising:

a chamber;

a substrate tray, for carrying a substrate;

a megasonic emission device, the megasonic emission device and the substrate tray being disposed in the chamber, the megasonic emission device being configured for transmitting megasonic energy to the chemical solution between the megasonic emission device and the substrate;

a grounded conductive nozzle, configured such that when the megasonic emission device is lowered above the substrate, the conductive nozzle first sprays the chemical solution onto the upper surface of the substrate, and when the megasonic emission device is immersed in the chemical solution film on the upper surface of the substrate, the charges on the megasonic emission device are conducted to the conductive nozzle through the chemical solution and are conducted away by the conductive nozzle.

Another embodiment of the present invention provides a substrate processing apparatus, comprising:

a chamber;

a substrate tray, for carrying a substrate;

a megasonic emission device, the megasonic emission device and the substrate tray being disposed in the chamber, the megasonic emission device being configured for transmitting megasonic energy to the chemical solution between the megasonic emission device and the substrate;

a cleaning device, for cleaning the megasonic emission device;

a first ion rod, provided within the chamber and disposed between the substrate tray and the cleaning device, the first ion rod having outlets facing upward such that when the megasonic emission device passes over the first ion rod in the course of movement between the substrate tray and the cleaning device, the first ion rod blowing ionic wind through the outlets toward the megasonic emission device above to neutralize charges on the megasonic emission device.

Another embodiment of the present invention provides a substrate processing apparatus, comprising:

a chamber;

a substrate tray, for carrying a substrate;

a megasonic emission device, the megasonic emission device and the substrate tray being disposed in the chamber, the megasonic emission device being configured for transmitting megasonic energy to the chemical solution between the megasonic emission device and the substrate;

a second ion rod, provided in an inner sidewall of the chamber;

a driving device, for driving the megasonic emission device to rotate such that the megasonic emission device rotates within the ionized wind-coverable area of the second ion rod.

As described above, the substrate processing apparatus of the present invention has the following advantages:

By providing an electrostatic elimination assembly, such as an electrostatic conductor assembly, an electric conductor, and ion rods, which are able to eliminate the static charges on the megasonic emission device and prevent the megasonic emission device from accumulating excessive residual charges. When the substrate is processed, the residual charges are prevented from discharging on the surface of the substrate, so as to avoid causing damage to the surface of the substrate.

Other features and corresponding beneficial effects of the present invention are described in later portions of the specification. It should be understood that at least some of the beneficial effects become apparent from the description of the present invention.

### BRIEF DESCRIPTION OF THE DRAWINGS

FIG. 1 shows a schematic diagram of the three-dimensional structure of the cleaning device and the megasonic emission device provided in embodiment 1 of the present invention;

FIG. 2 shows a three-dimensional schematic diagram of the cleaning device provided in embodiment 1 of the present invention;

FIG. 3 shows a three-dimensional structural schematic diagram of the electrostatic conductor assembly in the cleaning device provided in embodiment 1 of the present invention;

FIG. 4 is a schematic diagram of the three-dimensional structure of the electrostatic conductor assembly in the cleaning device provided in embodiment 1 of the present invention, wherein the shield is not shown;

FIG. 5 is a schematic diagram of a top view structure of the substrate processing apparatus provided in embodiment 2 of the present invention;

FIG. 6 shows a schematic diagram of the three-dimensional structure of the substrate processing apparatus provided in embodiment 2 of the present invention;

FIG. 7 is a schematic diagram of the three-dimensional structure of the megasonic emission device, the first cantilever, the first housing, the second cantilever, the second housing, and the screw rod provided in embodiment 2 of the present invention;

FIG. 8 is a schematic diagram of an elevation view of the electric conductor in contact with the first sidewall of the megasonic emission device provided in embodiment 2 of the present invention;

FIG. 9 is a schematic diagram of a three-dimensional structure of the electric conductor in contact with the first sidewall of the megasonic emission device provided in embodiment 2 of the present invention;

FIG. 10 is a schematic diagram of another view of the three-dimensional structure of the electric conductor in contact with the first sidewall of the megasonic emission device provided in embodiment 2 of the present invention;

FIG. 11 is a schematic diagram of the structure of the megasonic emission device having the electric conductor provided in embodiment 2 of the present invention when working above the substrate;

FIG. 12 is a schematic diagram of an elevation view of the structure provided in embodiment 2 of the present invention in which the electric conductor is not in contact with the first sidewall of the megasonic emission device;

FIG. 13 is a schematic diagram of a three-dimensional structure in which the electric conductor provided in embodiment 2 of the present invention is not in contact with the first sidewall of the megasonic emission device;

FIG. 14 is a schematic diagram of another view of the three-dimensional structure in which the electric conductor provided in embodiment 2 of the present invention is not in contact with the first sidewall of the megasonic emission device;

FIG. 15 is a schematic diagram of a three-dimensional structure of the electric conductor in contact with the second sidewall of the megasonic emission device provided in embodiment 2 of the present invention;

FIG. 16 is a schematic diagram of an elevation view of the electric conductor not in contact with the second sidewall of the megasonic emission device provided in embodiment 2 of the present invention;

FIG. 17 is a schematic diagram of a three-dimensional structure of the electric conductor in contact with the arcuate sidewall of the megasonic emission device provided in embodiment 2 of the present invention;

FIG. 18 is an elevation structural schematic diagram of the electric conductor not in contact with the arcuate sidewall of the megasonic wave emission device provided in embodiment 2 of the present invention;

FIG. 19 is a schematic diagram of a three-dimensional structure in which the electric conductor is not in contact with the arcuate sidewall of the megasonic emission device provided in embodiment 2 of the present invention;

FIG. 20 is a schematic diagram of an elevation view structure of the electric conductor in contact with the first sidewall, the second sidewall and the arcuate sidewall of the megasonic emission device provided in embodiment 2 of the present invention;

FIG. 21 is a schematic diagram of an elevation view of a structure in which the electric conductor is not in contact with the first sidewall, the second sidewall and the arcuate sidewall of the megasonic emission device provided in embodiment 2 of the present invention;

FIG. 22 is a schematic diagram of a three-dimensional structure of the conductive nozzle installed on a side of the megasonic emission device provided in embodiment 3 of the present invention;

FIG. 23 is a schematic diagram of a three-dimensional structure in another view of the conductive nozzle installed on one side of the megasonic emission device provided in embodiment 3 of the present invention;

FIG. 24 is a schematic diagram of an elevation view of the conductive nozzle installed on one side of the megasonic emission device provided in embodiment 3 of the present invention;

FIG. 25 is a schematic diagram of the three-dimensional structure of the conductive nozzle provided in embodiment 3 of the present invention;

FIG. 26 is a schematic diagram of the three-dimensional structure of the conductive nozzle provided in embodiment 3 of the present invention in another view;

FIG. 27 and FIG. 28 are schematic diagrams of the three-dimensional structure of the megasonic emission device provided in embodiment 3 of the present invention when working above the substrate;

FIG. 29 is a schematic diagram of the top view structure of the substrate processing apparatus provided in embodiment 4 of the present invention;

FIG. 30 is a schematic diagram of the three-dimensional structure of the substrate processing apparatus provided in embodiment 4 of the present invention;

FIGS. 31 and 32 are schematic diagrams of the three-dimensional structure of the substrate processing apparatus provided in embodiment 5 of the present invention;

FIGS. 33 and 34 are schematic diagrams of the three-dimensional structure of the second cantilever, the first cantilever, the megasonic emission device, and the screw rod provided with the driving device in embodiment 5 of the present invention;

FIG. 35 is a schematic structural diagram of the prior art in which a parallel capacitor is formed by the megasonic emission device, the chemical solution and the substrate; and

FIG. 36 is a schematic structural diagram of the prior art in which the residual charges accumulated on the megasonic emission device cause damage defects on the surface of the substrate.

### DETAILED DESCRIPTION OF EMBODIMENTS

The following description of the embodiments of the present invention is illustrated by particular specific embodiments, and other advantages and efficacies of the present invention can be readily appreciated by those skilled in the technical field from what is disclosed in this specification. Although the description of the present invention will be presented in conjunction with the preferred embodiments, this does not mean that the characterization of the invention is limited to the embodiment. Quite to the contrary, the presentation of the invention in conjunction with the embodiments is intended to cover other options or modifications that may be extended based on the claims of the invention. In order to provide a deeper understanding of the present invention, many specific details will be included in the following description. The invention may also be implemented without the use of these details. In addition, some specific details will be omitted from the description in order to avoid confusing or obscuring the focus of the invention. It is to be noted that embodiments and features in embodiments of the present invention may be combined with each other without conflict.

It should be noted that in this specification, similar labels and letters denote similar items in the following accompanying drawings, so that once an item is defined in one accompanying drawing, it need not be further defined and explained in subsequent accompanying drawings.

The technical solution of the present invention will be described clearly and completely in the following in conjunction with the accompanying drawings. It is obvious that the described embodiments are a part of the embodiments of the present invention and not all of the embodiments. Based on the embodiments of the present invention, all the other embodiments obtained by the person of ordinary skill in the field under the premise of not making creative labor, all belong to the scope of protection of the present invention.

In the description of the present invention, it is to be noted that the terms “center”, “up”, “down”, “left” “right”, “vertical”, “horizontal”, “inside”, “outside” indicate an orientation or positional relationship based on those shown in the accompanying drawings. The above terms are intended only for the convenience of describing the present invention and for simplifying the description, and are not intended to indicate or imply that the device or element referred to must be constructed and operated with a particular orientation, and therefore are not to be construed as a limitation of the present invention. Furthermore, the terms “first”, “second”, “third” are used for descriptive purposes only and are not to be understood as indicating or implying relative importance.

In the description of the present invention, it is to be noted that, unless otherwise expressly specified and limited, the terms “install”, “connect”, “contact” are to be understood in a broad sense, e.g., it may be a fixed connection, a removable connection, or an integrated connection; it may be a mechanical connection or an electrical connection; it may be a direct connection or a connection through an intermediate medium; it may be a connection within two elements. For those of ordinary skill in the field, the above terms will be understood in the specific context.

In order to make the purposes, technical solutions and advantages of the present invention clearer, embodiments of the present invention will be described in further detail below in conjunction with the accompanying drawings.

### First Embodiment

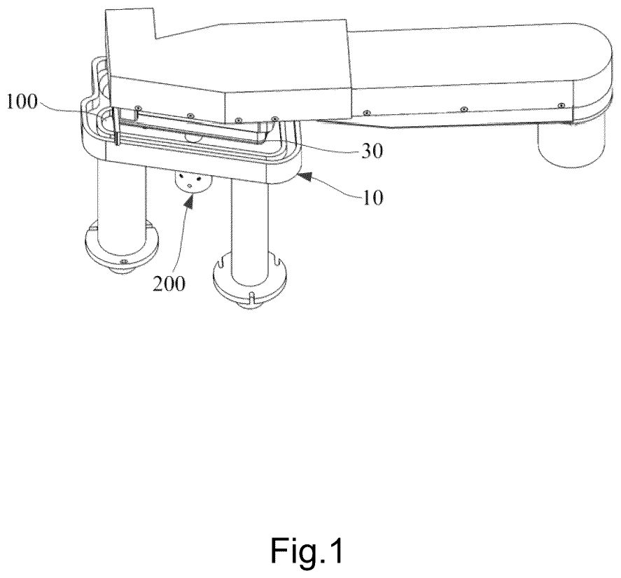

A megasonic emission device (e.g., megasonic emission device 30 in FIG. 1) can be

applied in a substrate cleaning process, as well as in a substrate pre-wetting process, etc., without limitation herein.

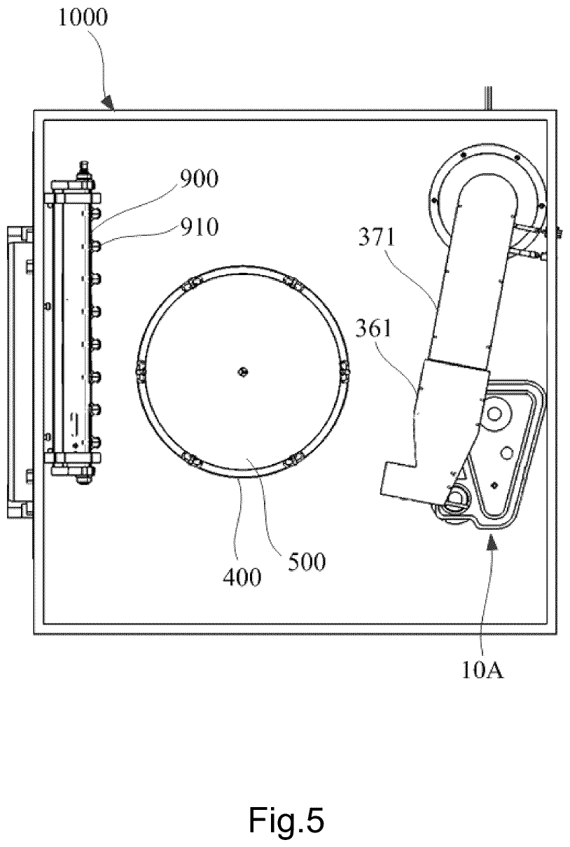

Taking a substrate cleaning process as an example, it is understood by the person skilled in the field that in the substrate cleaning process, a substrate tray (refer to the substrate tray 400 in FIG. 5) inside the chamber carries a substrate and rotates the substrate (refer to the substrate 500 in FIG. 5). A plurality of edge clamps are provided on the edges of the substrate tray, and the clamps clamp the substrate in place. The megasonic emission device is moved to a position above the surface of the substrate, and at least one nozzle sprays the chemical solution onto the surface of the substrate. The megasonic emission device descends and is immersed in the chemical solution, and the distance of the chemical solution film between the megasonic emission interface and the surface of the substrate is varied by controlling the up and down movement of the megasonic emission device, so as to make the megasonic integral energy received by each point on the substrate in one cycle consistent, thereby making the energy of each point on the substrate uniform. A method for cleaning a substrate using a megasonic emission device is described in detail in the Chinese invention patent with the announcement number CN101879511B, which is incorporated herein by reference.

In the substrate cleaning process, although the megasonic emission device is in direct contact with the chemical solution, the edge clamps that hold the edges of the substrate on the substrate tray are generally non-conductive insulating materials, so that the charges accumulated on the megasonic emission device are not efficiently conducted and eliminated by the chemical solution. When the uneliminated residual charges accumulate to a certain amount, a discharge phenomenon occurs on the surface of the substrate, causing damage to the surface of the substrate.

Accordingly, the present invention proposes a cleaning device of a substrate processing apparatus. After the substrate cleaning process is completed, the megasonic emission device is cleaned and the residual charges on the megasonic emission device is eliminated at the same time.

Referring to FIG. 1, after the substrate cleaning process is completed, the megasonic emission device 30 returns to the initial position for self-cleaning in the cleaning device 10 used to clean the megasonic emission device 30. At this point, the megasonic emission device 30 stops emitting radio-frequency energy and does not generate additional surface charges.

The cleaning device 10 provided by the present invention can conduct residual charges accumulated on the megasonic emission device 30 away to eliminate the charges accumulated on the megasonic emission device 30.

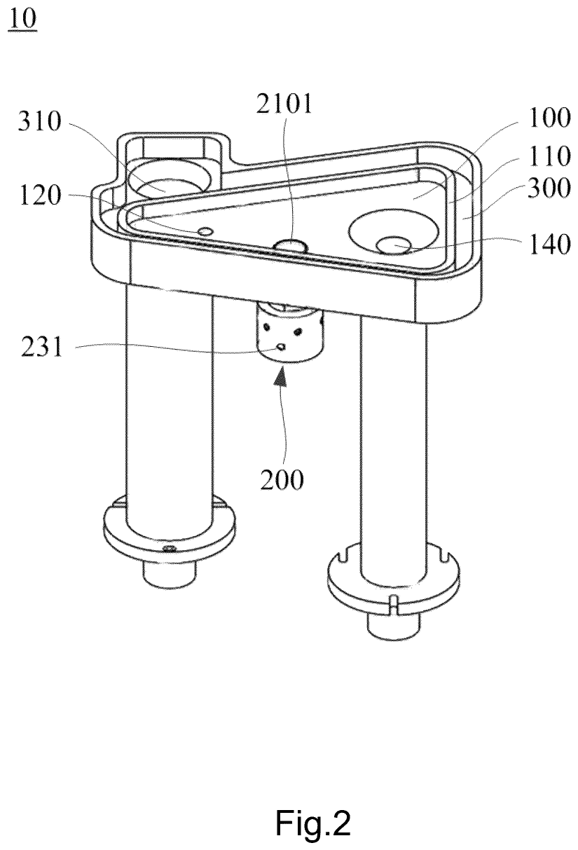

Referring to FIG. 2, the cleaning device 10 includes a cleaning tank 100 and an electrostatic conductor assembly 200. The cleaning tank 100 is used to hold the cleaning solution to clean the megasonic emission device 30. The electrostatic conductor assembly 200 is provided in the cleaning tank 100 of the cleaning device 10, and the electrostatic conductor assembly 200 is used to electrically connected with the megasonic emission device 30 to conduct the charges accumulated on the megasonic emission device 30 away.

In this embodiment, pure water of 0.1 megohm mixed with CO₂ is selected to be used as the cleaning solution. The cleaning tank 100 is made of organic material, such as PTFE (Poly Tetra Fluoro Ethylene) or PFA (Poly Fluoro Alkoxy) material, which can be considered non-conductive. The present invention provides an electrostatic conductor assembly 200 for electrically connection with the megasonic emission device 30 on the cleaning tank 100 of the cleaning device 10, so that the charges on the megasonic emission device 30 can be conducted away through the electrostatic conductor assembly 200. Therefore, damage defects on the surface of the substrate due to the residual charges accumulated on the megasonic emission device 30 can be avoided during the cleaning process of the substrate.

In other alternative embodiments, by providing an electrostatic conductor assembly 200 on the cleaning tank 100 of the cleaning device 10, the electrostatic conductor assembly 200 can be brought into direct contact with the megasonic emission device 30. The charges accumulated on the megasonic emission device 30 is directly conducted away from the electrostatic conductor assembly 200.

In conjunction with FIGS. 1 to 2, the electrostatic conductor assembly 200 is fixed to the bottom of the cleaning tank 100 (i.e., the bottom of the cleaning device 10), and the electrostatic conductor assembly 200 is grounded.

When the megasonic emission device 30 is cleaned in the cleaning tank 100 of the cleaning device 10, the electrostatic conductor assembly 200 is electrically connected to the megasonic emission device 30 via the cleaning solution in the cleaning tank 100 so that the charges accumulated on the megasonic emission device 30 are sequentially conducted away by the cleaning solution and the electrostatic conductor assembly 200.

The electrostatic conductor assembly 200 includes a connection terminal 210 and a wire

220, the connection terminal 210 and the wire 220 are electrically connected. The connection terminal 210 is fixed to the bottom of the cleaning tank 100, and the wire 220 is grounded.

Furthermore, the first end 2101 of the connection terminal 210 runs through the bottom of the cleaning tank 100 and is fixed to the bottom of the cleaning tank 100 in a screwed connection. The first end 2101 of the connection terminal 210 is in contact with the cleaning solution, and the second end 2102 of the connection terminal 210 is connected to the wire 220. Specifically, the threaded connection is an NPT (national pipe thread) threaded connection.

In this embodiment, the connection terminal 210 is electrically conductive, and the wire 220 is fixed to the second end 2102 of the connection terminal 210 by the fixing bolt 240.

The connection terminal 210 may also be non-conductive, and a cavity may be provided within the connection terminal 210 such that the wire 220 is electrically connected to the cleaning solution through the cavity.

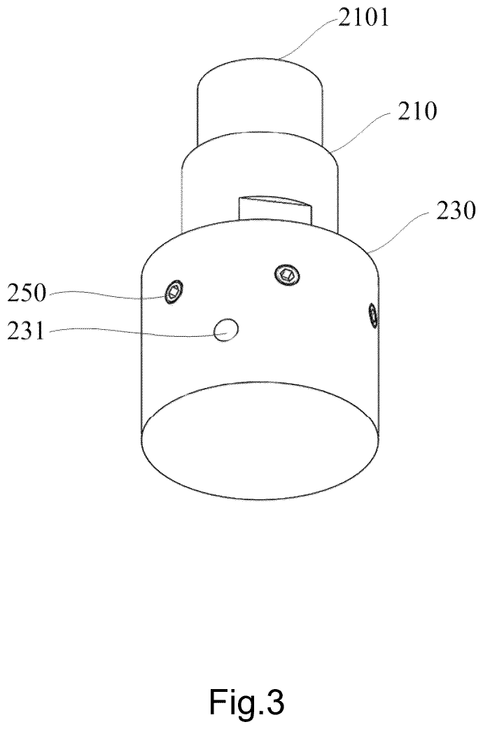

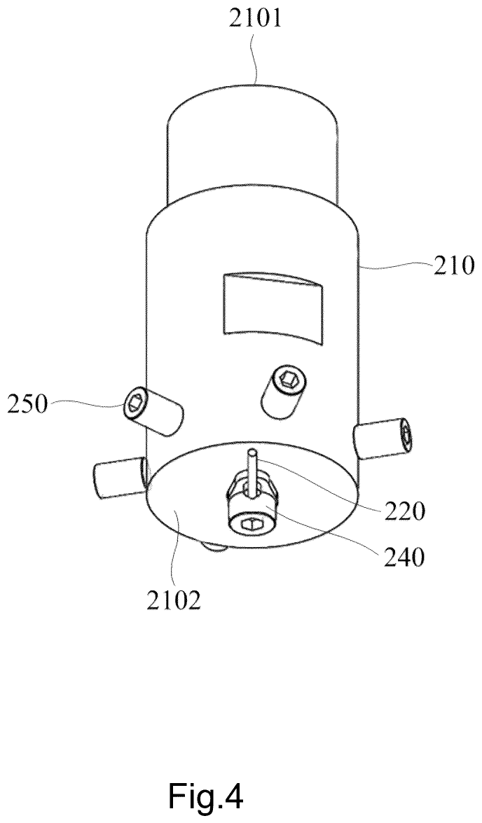

In conjunction with FIGS. 3 and 4, the electrostatic conductor assembly 200 further comprises a shield 230 covering the second end 2102 of the connection terminal 210. The second end 2102 of the connection terminal 210 extends outside of the cleaning tank 100. Accordingly, the shield 230 is located outside of the cleaning tank 100, and the sidewall of the shield 230 is secured to the outer periphery of the connection terminal 210 by means of a number of top wires 250. The shield 230 may partially cover the portion of the connection terminal 210 that extends to the outside of the cleaning tank 100, including covering the second end 2102 of the connection terminal 210, mainly to cover the position where the connection terminal 210 exposes the wire 220, so as to prevent the wire 220 from being subjected to external interference and resulting in poor contact. The shield 230 may also completely cover the portion of the connection terminal 210 that extends outside of the cleaning tank 100 to prevent corrosion, leakage, etc., of that portion of the connection terminal 210.

The sidewall of the shield 230 is also provided with a through-hole 231 through which the wire 220 secured to the second end 2102 of the connection end 210 passes and is grounded.

Referring to FIG. 2, the cleaning device 10 further includes an overflow tank 300, an inlet 120, and outlets. The overflow tank 300 surrounds the cleaning tank 100. The partition wall 110 is provided between the overflow tank 300 and the cleaning tank 100. The excess cleaning solution in the cleaning tank 100 flows through the partition wall 110 into the overflow tank 300, and is discharged from the outlets.

The outlets include a first outlet 140 and a second outlet 310, both the inlet 120 and the first outlet 140 are connected to the cleaning tank 100. The inlet 120 is used to pass the cleaning solution into the cleaning tank 100. The first outlet 140 is used to drain the cleaning solution from the cleaning tank 100; the second outlet 310 is connected to the overflow tank 300, and the second outlet 310 is used to drain the cleaning solution from the overflow tank 300.

Further, the inlet 120 and the first outlet 140 are provided at the bottom of the cleaning tank 100. The second outlet 310 is provided at the bottom of the overflow tank 300.

### Second Embodiment

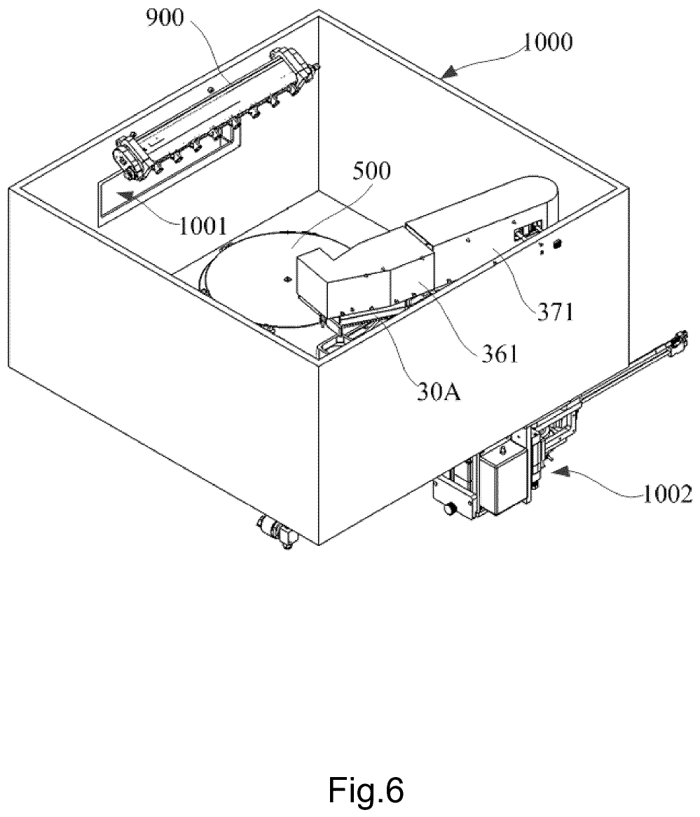

Referring to FIGS. 5 and 6, the present invention proposes a substrate processing apparatus comprising a chamber 1000, a substrate tray 400, a cleaning device 10A, and a megasonic emission device 30A. The cleaning device 10A may be an existing cleaning device, or the cleaning device 10 in embodiment 1 may be used.

The substrate tray 400, the cleaning device 10A and the megasonic emission device 30A are provided in the chamber 1000. The substrate tray 400 is used to carry the substrate 500. The megasonic emission device 30A is used to transmit megasonic energy to the chemical solution between the megasonic emission device 30A and the substrate 500 in order to treat the substrate 500 and be moved to the cleaning device 10A for self-cleaning after the process is completed.

As an example of a substrate cleaning process, the method of cleaning a substrate includes the following steps:

Clamp the substrate 500 by means of the substrate tray 400;

Spray the chemical solution onto the upper surface of the substrate 500;

The megasonic emission device 30A is moved above the substrate 500 and the megasonic emission device 30A is lowered to form a gap between the megasonic emission device 30A and the upper surface of the substrate 500;

The substrate tray 400 is rotated to ensure that the gap between the megasonic emission device 30A and the upper surface of the substrate 500 is completely and consistently filled with the cleaning solution so that the megasonic energy is steadily transferred through the cleaning solution to the entire surface of the substrate 500.

A method for cleaning a substrate is described in detail in the Chinese invention patent with Publication No. CN109890520A, which is incorporated herein by reference.

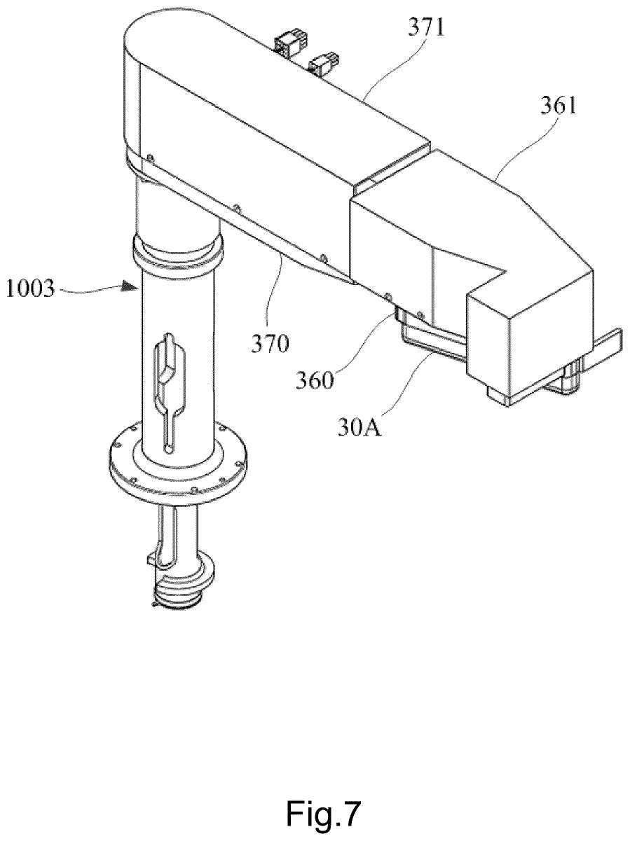

In conjunction with FIGS. 6 and 7, the substrate processing apparatus includes a first cantilever 360 and a second cantilever 370 interconnected. The first cantilever 360 is installed on top of the megasonic emission device 30A, and the first cantilever 360 has a first housing 361 thereon. The actuator 1002 of the substrate processing apparatus actuates the second cantilever 370 upwardly or downwardly by means of the screw rod 1003, as well as actuating the second cantilever 370 to rotate so that the megasonic emission device 30A moves above the substrate 500 or changes the gap between the megasonic emission device 30A and the upper surface of the substrate 500. The second cantilever 370 has a second housing 371 thereon.

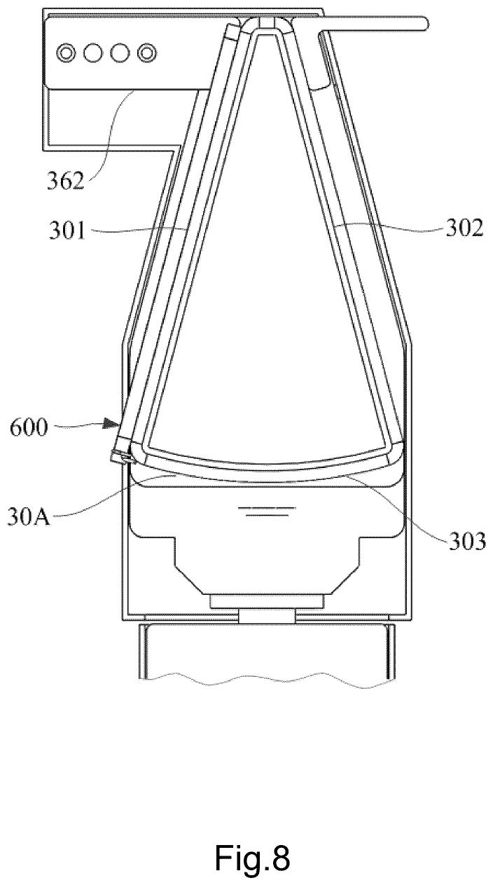

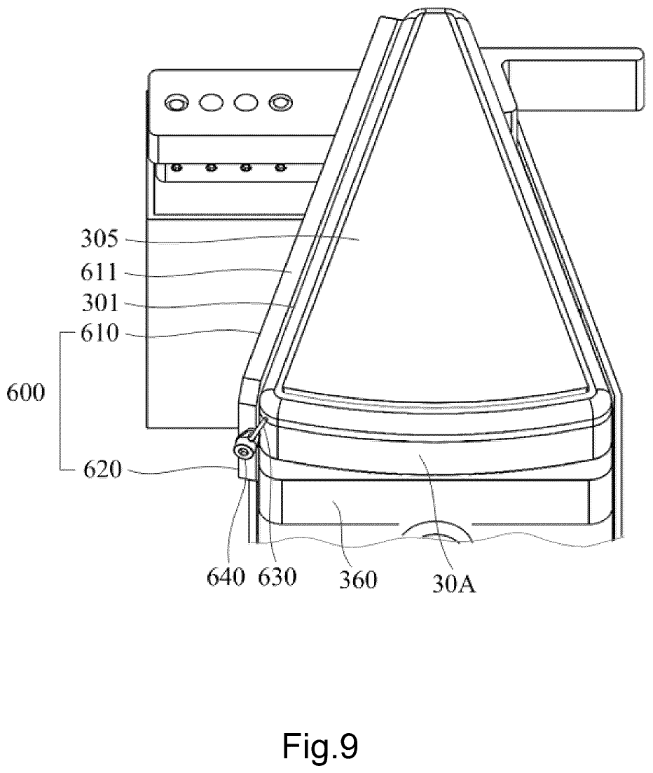

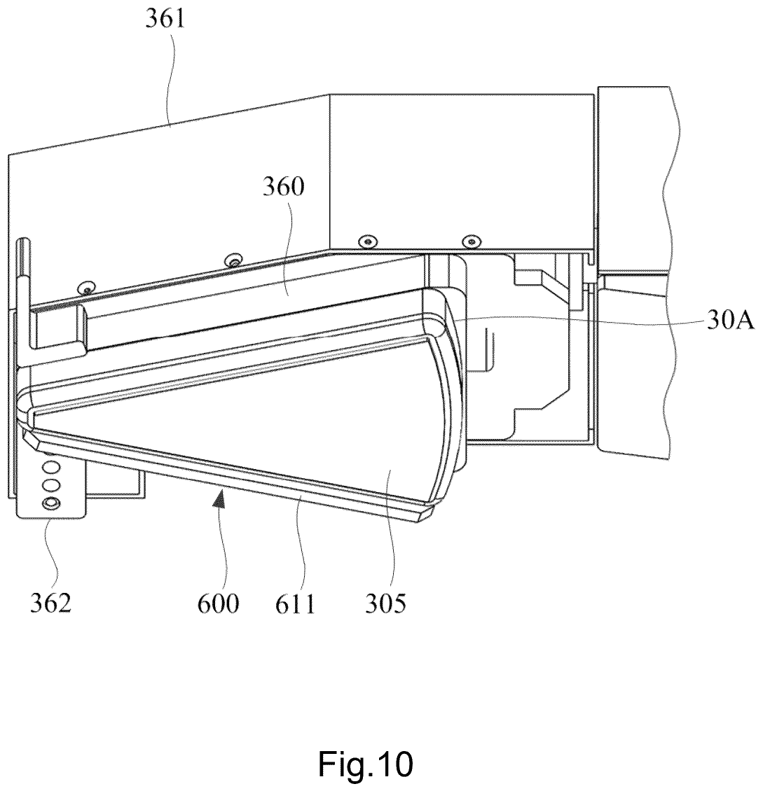

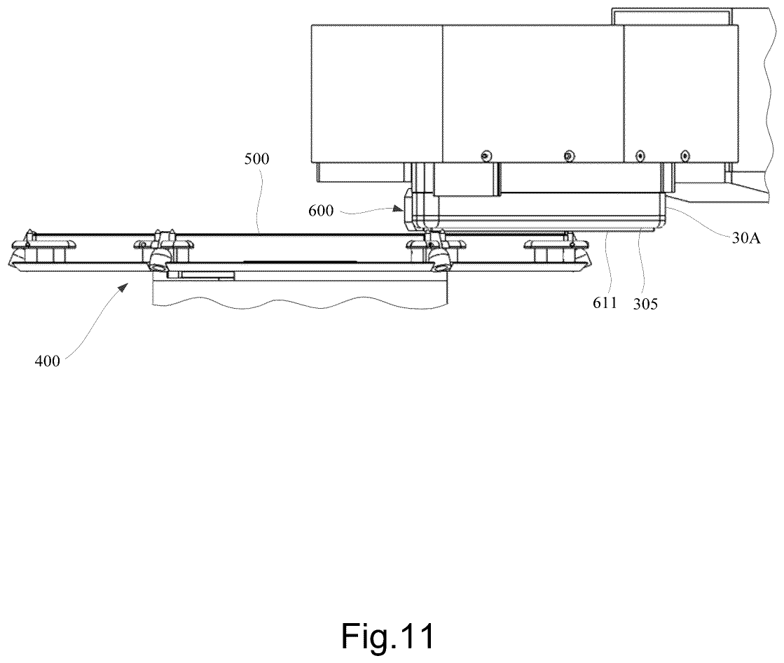

In conjunction with FIGS. 8 to 11, the substrate processing apparatus further includes an electric conductor 600 to which a ground wire 630 is electrically connected via a connector 640.

The electric conductor 600 is configured such that the lower surface 611 of the electric conductor 600 contacts the chemical solution on the upper surface of the substrate 500 before the lower surface 305 of the megasonic emission device 30A. When the megasonic emission device 30A is immersed in the chemical solution on the upper surface of the substrate 500, the charges on the megasonic emission device 30A are conducted away through the chemical solution to the electric conductor 600 and are conducted away by the electric conductor 600. Then, the megasonic emission device 30A is turned on to transfer megasonic energy to the chemical solution between the megasonic emission device 30A and the substrate 500 so that the megasonic energy is transmitted to the entire surface of the substrate 500 through the chemical solution in a stable manner. After the megasonic emission device 30A is turned on, the electric conductor 600 can still be electrically conductive to eliminate static electricity generated during the treatment of the substrate 500. In this embodiment, a center nozzle 362 is used to spray the chemical solution onto the upper surface of the substrate 500. The center nozzle 362 is provided on the first cantilever 360, which is integrated with the megasonic emission device 30A. In other alternative embodiments, a separate nozzle may also be used to spray the chemical solution onto the upper surface of the substrate 500.

Alternatively, during the descent of the megasonic emission device 30A, the lower surface 305 of the megasonic emission device 30A is kept parallel to the upper surface of the substrate 500 on the substrate tray 400. Alternatively, the lower surface 305 of the megasonic emission device 30A is firstly tilted relative to the upper surface of the substrate 500 so that the charges on the megasonic emission device 30A are conducted away by the chemical solution and the electric conductor 600. And then the lower surface 305 of the megasonic emission device 30A is kept parallel to the upper surface of the substrate 500. And then the megasonic emission device 30A is turned on in order to perform the treatment of the substrate 500.

The shape of the megasonic emission device 30A may be a polygon, an oval, a semicircle, a quarter-circle, or a circle, and the like. The shape of the electric conductor 600 varies according to the shape of the megasonic emission device 30A.

Preferably, the megasonic emission device 30A is shaped in the form of a triangle or a pie shape similar to a triangle (i.e., a pie shape similar to a triangle). The electric conductor 600 is disposed at a location of at least one of the first sidewall 301, the second sidewall 302, and the third sidewall 303 of the megasonic emission device 30A. The lower surface 611 of the electric conductor 600 extends beyond the lower surface 305 of the megasonic emission device 30A.

Referring to FIGS. 8 to 10, an electric conductor 600 is located at the position of the first sidewall 301 of the megasonic emission 30A. The electric conductor 600 is, for example, a conductive rod or a conductive block comprising a conductive portion 610 and a fixing portion 620. The conductive portion 610 is secured by means of the fixing portion 620 to the first cantilever 360, and the conductive portion 610 is in contact with the first sidewall 301 of the megasonic emission 30A. The lower surface 611 of the electric conductor 610 extends beyond the lower surface 305 of the megasonic emission device 30A. Since the lower surface 611 of the electric conductor 600 first contacts the chemical solution on the upper surface of the substrate 500, when the megasonic emission device 30A is immersed in the chemical solution film on the upper surface of the substrate 500, according to the fact that the electrons will preferentially conduct in the path of low resistance, the charges on the megasonic emission device 30A will be conducted through the chemical solution to the grounded electric conductor 600 and will be conducted away from the side, avoiding the charges onto the substrate 500.

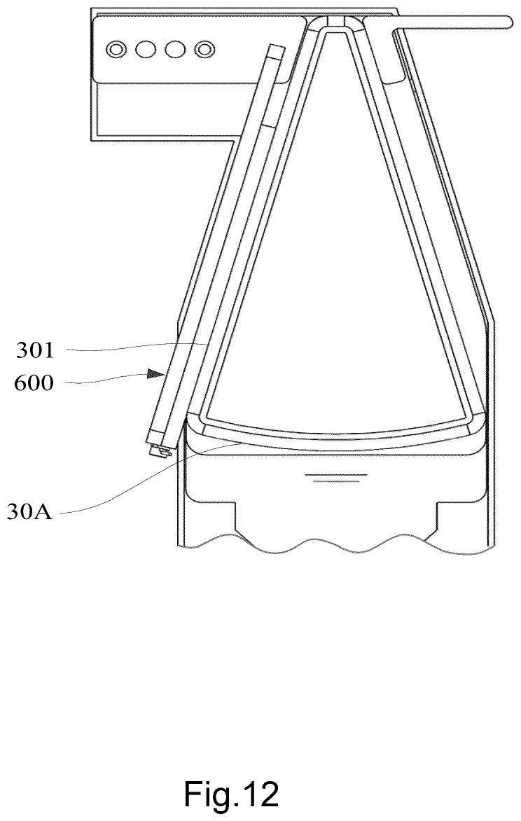

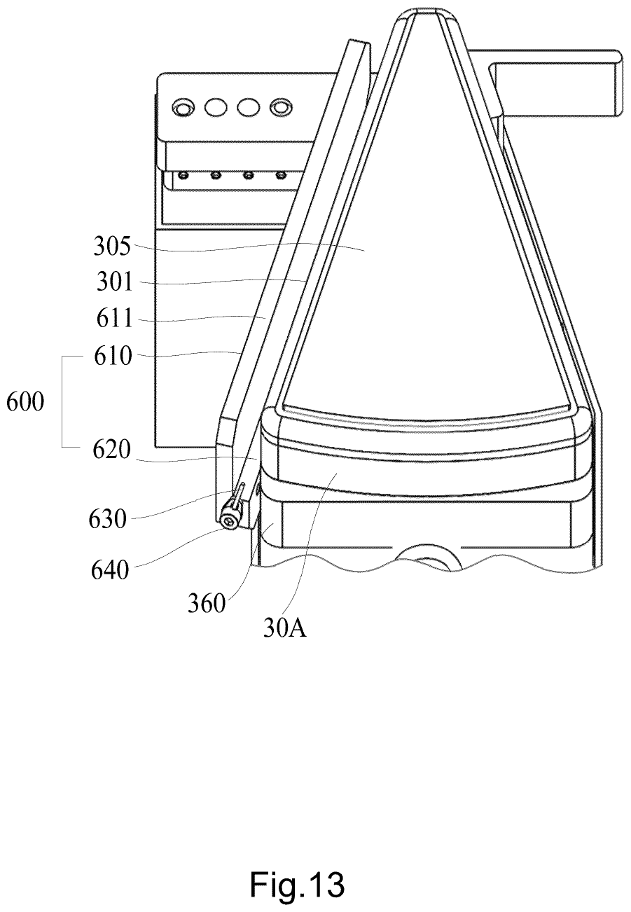

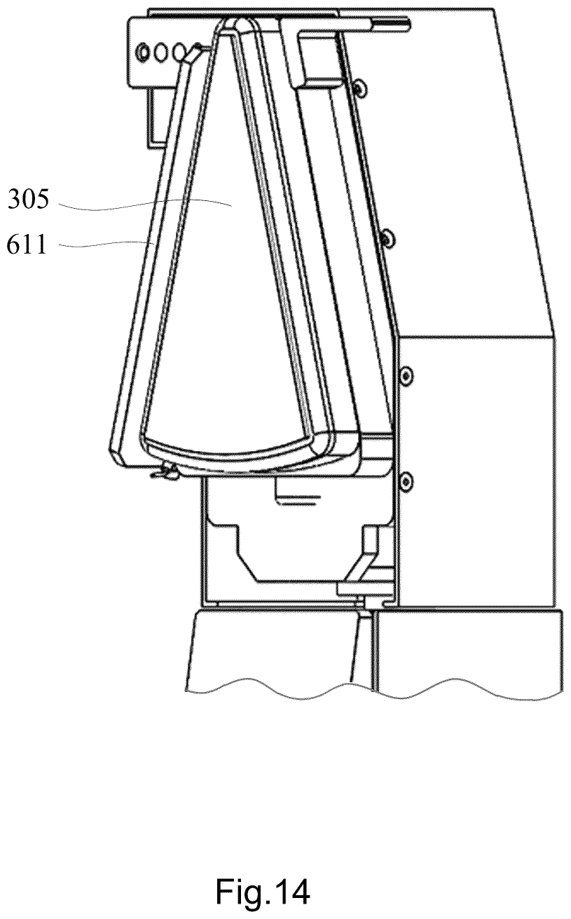

Referring to FIGS. 12 to 14, the conductive portion 610 of the electric conductor 600 and the first sidewall 301 of the megasonic emission device 30A may also be out of contact, that is, there is a gap between the conductive portion 610 of the electric conductor 600 and the first sidewall 301 of the megasonic emission device 30A, and the electric conductor 600 itself may be grounded to conduct the charges. Similarly, based on the fact that electrons will preferentially conduct to paths with low resistance, the charges on the megasonic emission device 30A will be conducted away from the side through the chemical solution to the grounded electric conductor 600, avoiding the charges to the substrate 500. In this embodiment, the fixing portion 620 can be screwed to the sidewall of the first cantilever 360.

In other embodiments, regardless of whether the conductive portion 610 of the electric conductor 600 is in contact with the first sidewall 301 of the megasonic emission device 30A, the conductive portion 610 of the electric conductor 600 may be tilted with respect to the first sidewall 301 of the megasonic emission device 30A, so that the conductive portion 610 is in contact with the chemical solution before the megasonic emission device 30A docs.

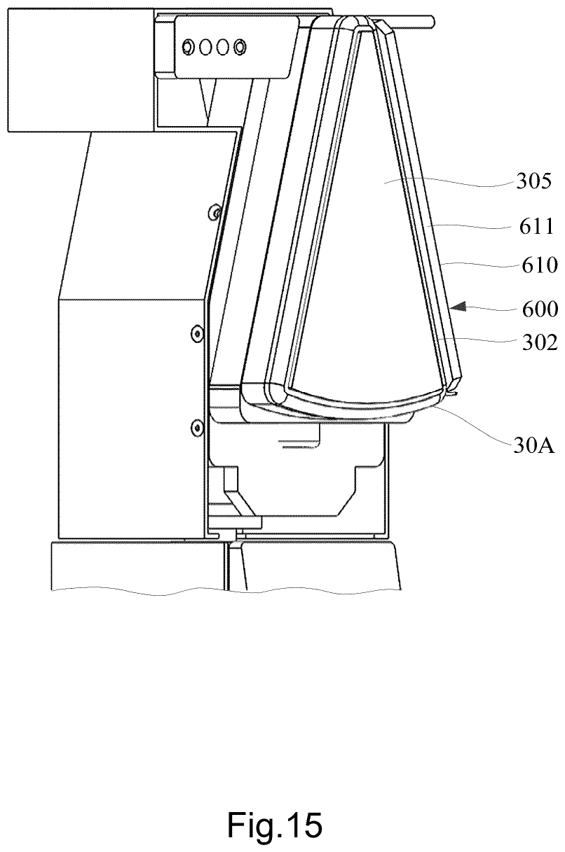

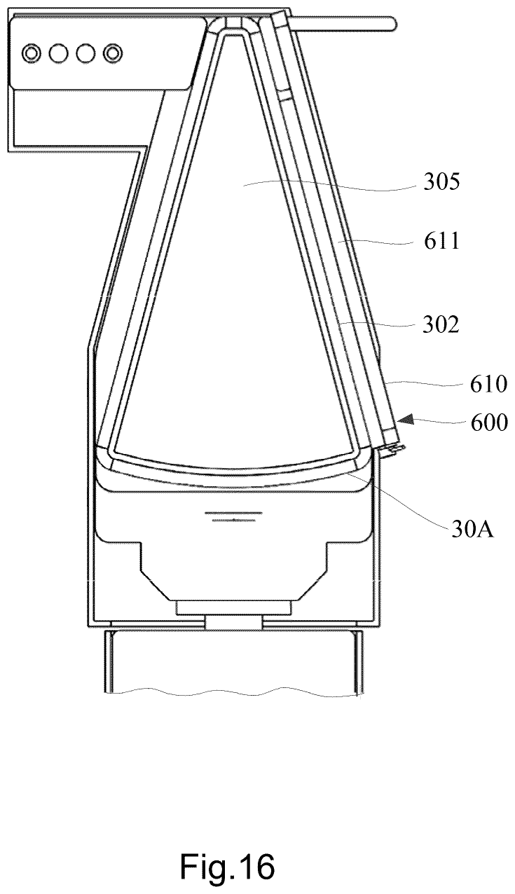

Similarly, see FIG. 15, the electric conductor 600 may also be disposed on the second sidewall 302 of the megasonic emission device 30A, with the conductive portion 610 of the electric conductor 600 coming into contact with the second sidewall 302 of the megasonic emission device 30A. Referring to FIG. 16, the electrically conductive portion 610 of the electric conductor 600 may also not be in contact with the second sidewall 302 of the megasonic emission device 30A. In other embodiments, both the first sidewall 301 and the second sidewall 302 of the megasonic emission device 30A may be provided with the electric conductor 600 such that the electric conductor 600 contacts the chemical solution before the megasonic emission device 30A does.

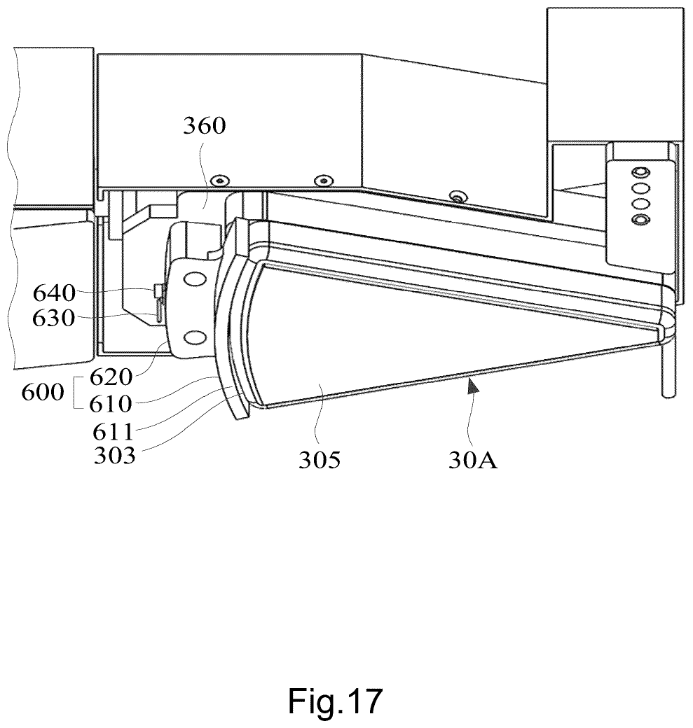

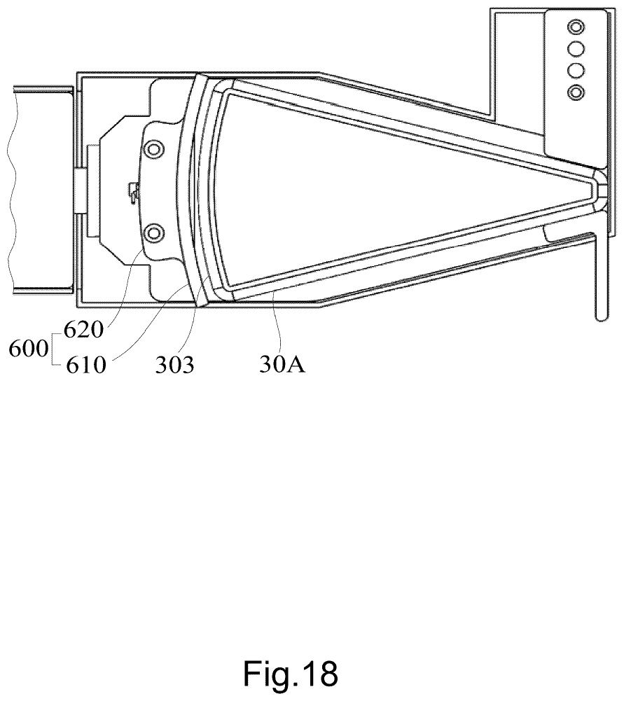

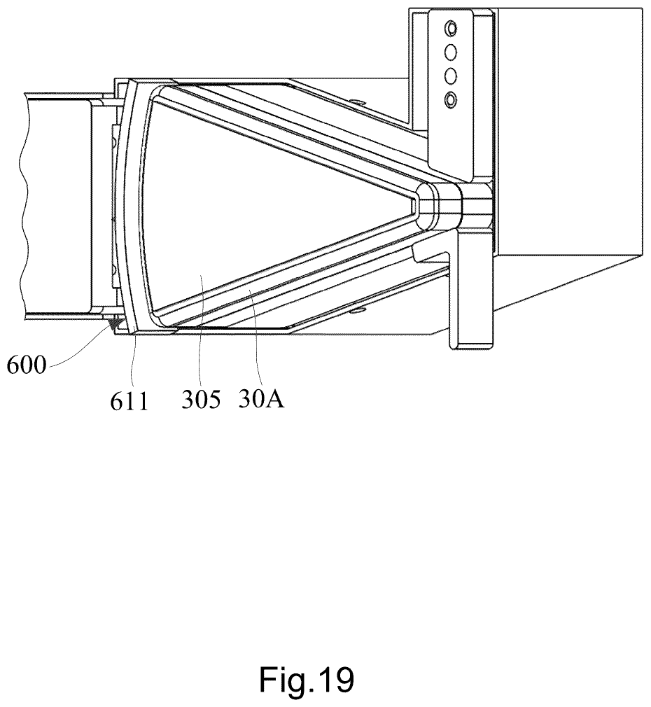

The electric conductor 600 may also be provided on the third sidewall 303 of the megasonic emission device 30A, and the shape of the electric conductor 600 is changed according to the shape of the third sidewall 303. The conductive portion 610 of the electric conductor 600 is electrically connected to the fixing portion 620, and the grounding wire 630 is electrically connected to the electric conductor 600 through the connector 640 on the fixing portion 620. The fixing portion 620 is fixed to the first cantilever 360, and the conductive portion 610 of the electric conductor 600 is in contact (see FIG. 17) or not in contact (see FIGS. 18 and 19) with the third sidewall 303 of the megasonic emission device 30A.

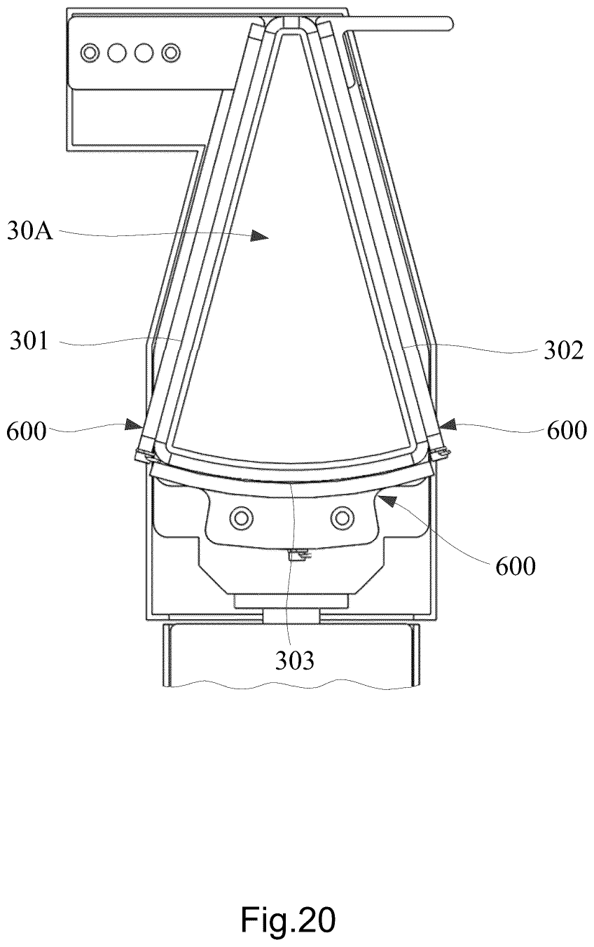

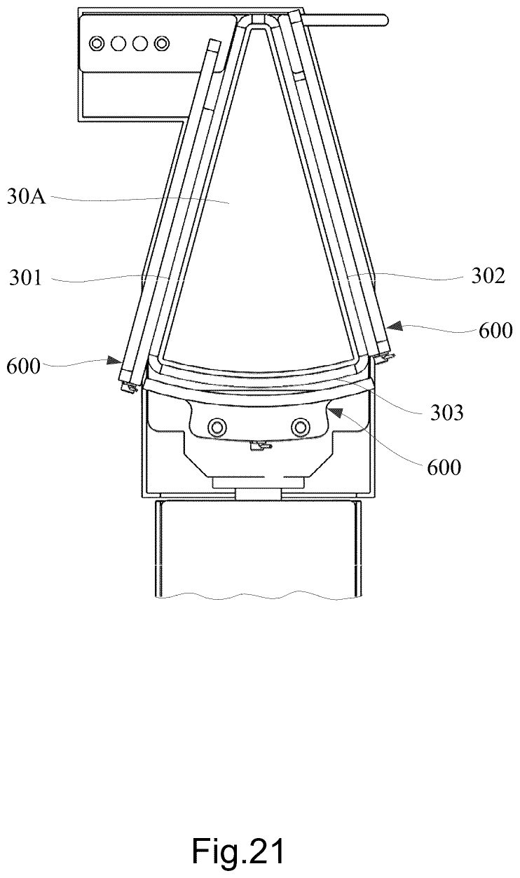

Further, the first sidewall 301, the second sidewall 302 and the third sidewall 303 of the megasonic emission device 30A may be provided with the electric conductor 600, and the conductive portion 610 of the conductor 600 is in contact (see FIG. 20) or is not in contact (sec FIG. 21) with the first sidewall 301, the second sidewall 302 and the third sidewall 303 of the megasonic emission device 30A such that the electric conductor 600 contacts the chemical solution before the megasonic emission device 30A does.

In this embodiment, the material of the electric conductor 600 may be the antistatic conductive material such as ESD PTFE, ESD PEEK, ESD PCTFE, ESD ETFE or ESD PFA.

The lower surface 611 of the conductive portion 610 of the electric conductor 600 can also be flush with the lower surface 305 of the megasonic emission device 30A. The lower surface 611 of the electric conductor 600 and the lower surface 305 of the megasonic emission device 30A are simultaneously in contact with the chemical solution on the upper surface of the substrate 500, so that the charges on the megasonic emission device 30A are conducted to the electric conductor 600 through the chemical solution and are conducted away by the electric conductor 600.

### Third Embodiment

The substrate processing apparatus proposed in this embodiment, referring to FIGS. 5 and 6 of embodiment 2, includes a chamber 1000, a substrate tray 400, a cleaning device 10A, and a megasonic emission device 30A. The cleaning device 10A may be an existing cleaning device, or the cleaning device 10 in embodiment 1 may be used.

The substrate tray 400, the cleaning device 10A and the megasonic emission device 30A are located in the chamber 1000. The substrate tray 400 is used to carry the substrate 500. The megasonic emission device 30A is used to transmit megasonic energy to the chemical solution between the megasonic emission device 30A and the substrate 500 to treat the substrate 500 and be moved to the cleaning device 10A for self-cleaning after the process is completed.

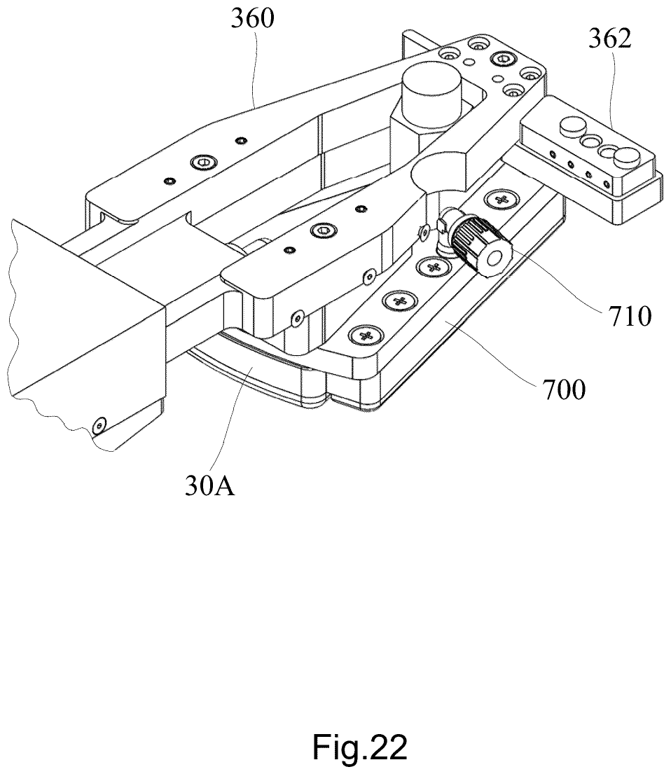

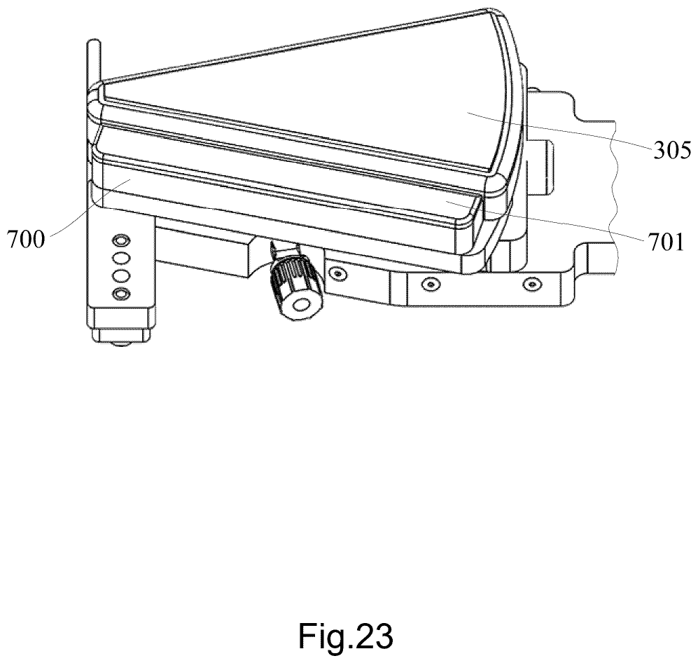

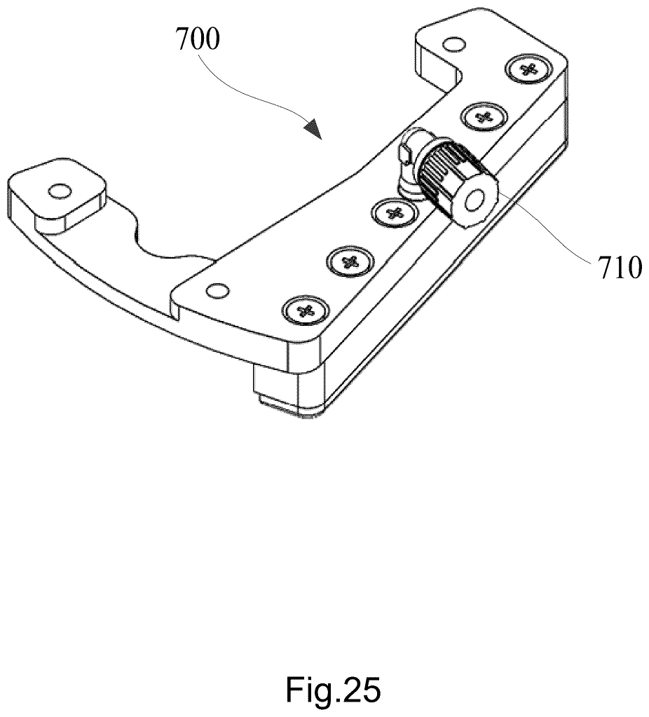

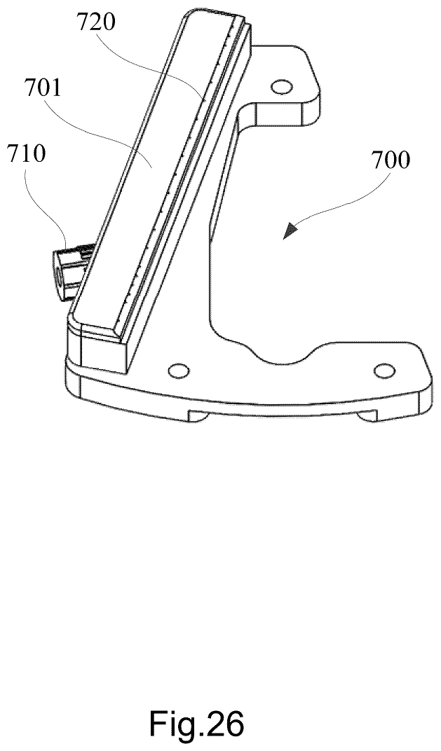

Referring to FIGS. 22 to 24, the conductive nozzle 700 is provided on one side of the megasonic emission device 30A. Referring to FIGS. 25 and 26, the conductive nozzle 700 has an inlet port 710 and a plurality of outlet ports 720, with the inlet port 710 being provided at the top of the conductive nozzle 700, and the plurality of outlet ports 720 being evenly distributed at the bottom of the conductive nozzle 700.

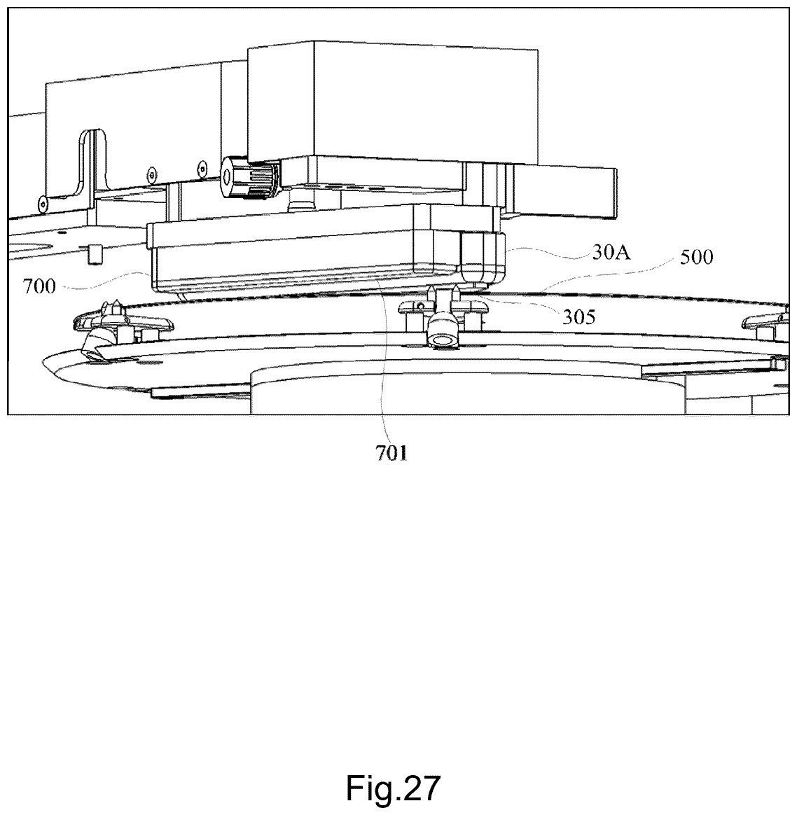

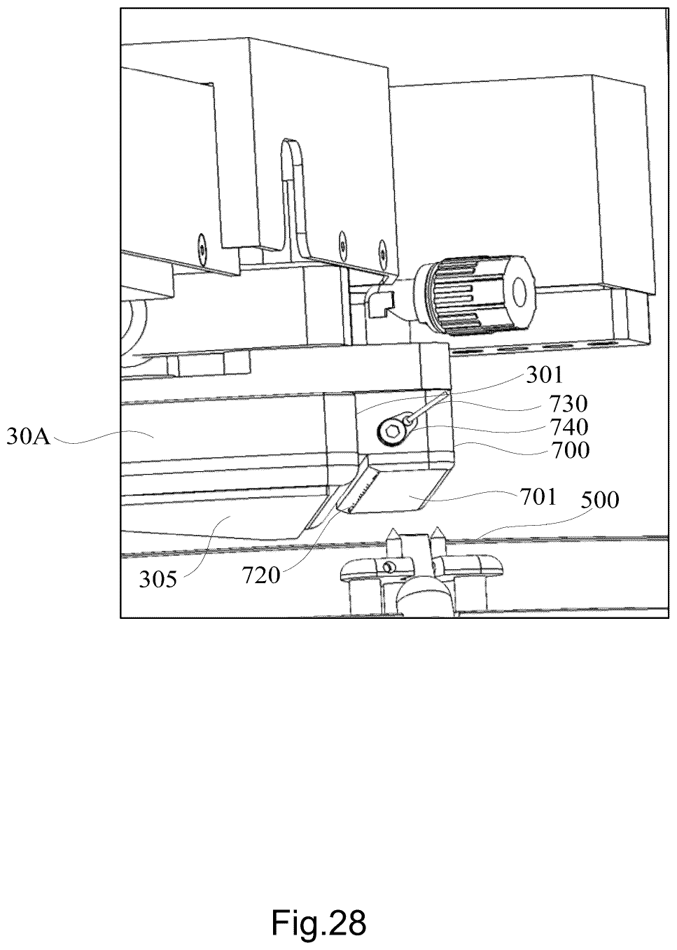

Referring to FIGS. 27 and 28, the conductive nozzle 700 is configured such that when the megasonic emission device 30A is lowered above the substrate 500, the conductive nozzle 700 first sprays the chemical solution to the upper surface of the substrate 500 through the plurality of liquid outlet ports 720. When the megasonic emission device 30A is immersed in the chemical solution film on the upper surface of the substrate 500, the charges on the megasonic emission device 30A are conducted to the conductive nozzle 700 through the chemical solution and are conducted away by the conductive nozzle 700, thereby eliminating the static electricity on the megasonic emission device 30A, wherein the ground wire 730 is electrically connected to the conductive nozzle 700 through the connector 740.

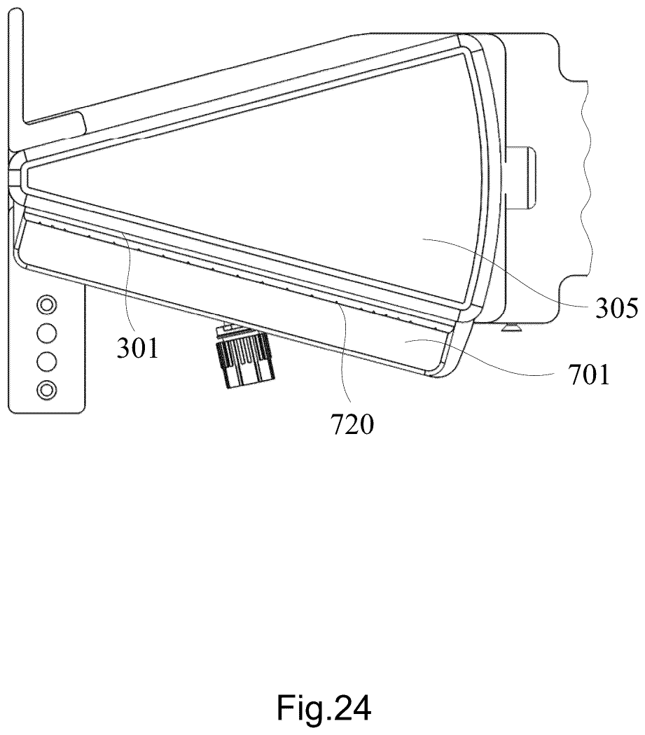

In conjunction with FIGS. 24 and 28, the conductive nozzle 700 is in contact with the first sidewall 301 of the megasonic emission device 30A. In other embodiments, the conductive nozzle 700 and the first sidewall 301 of the megasonic emission device 30A may also be spaced apart, that is, set up so as not to contact.

The lower surface 701 of the conductive nozzle 700 is higher than the lower surface 305 of the megasonic emission device 30A. In other embodiments, the lower surface 701 of the conductive nozzle 700 may also be lower than or flush with the lower surface 305 of the megasonic emission device 30A, depending on the actual requirements.

In addition, while the conductive nozzle 700 sprays the chemical solution, the center nozzle 362 set at the end of the first cantilever 360 can also spray the chemical solution to the upper surface of the substrate 500. By controlling the rotational speed of the substrate tray 400, the gap between the megasonic emission device 30A and the upper surface of the substrate 500 is completely and continuously filled with the chemical solution, so that the megasonic energy is transmitted to the entire surface of the substrate 500 through the chemical solution in a stable manner. In other embodiments, only the conductive nozzle 700 may be used to spray the chemical solution onto the upper surface of the substrate 500.

In this embodiment, the conductive nozzle 700 is made of the anti-static conductive material such as ESD PTFE, ESD PEEK, ESD PCTFE, ESD ETFE, or ESD PFA.

### Fourth Embodiment

Embodiment 4 presents another embodiment of eliminating static electricity on the megasonic emission device 30A. A first ion rod 800 is employed to neutralize the charges on the megasonic emission device 30A.

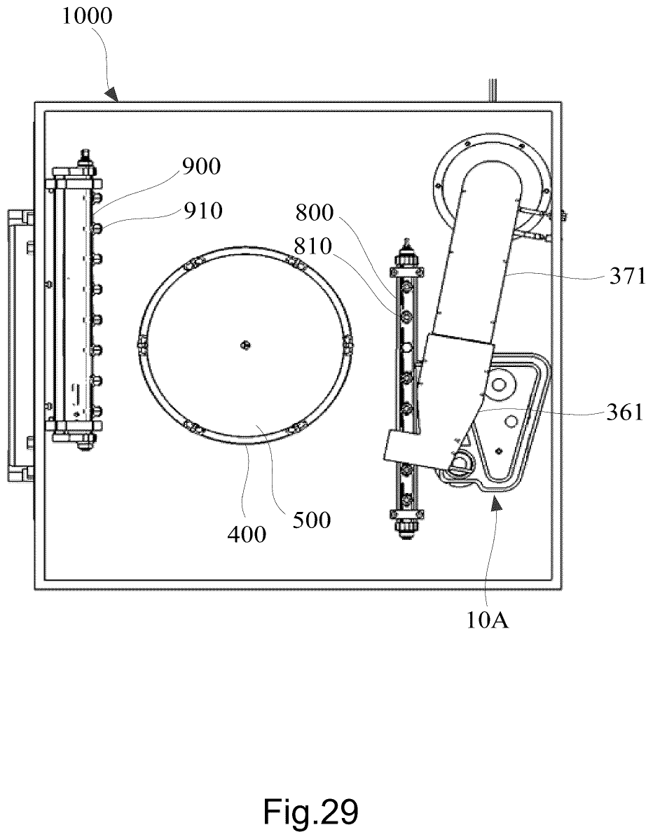

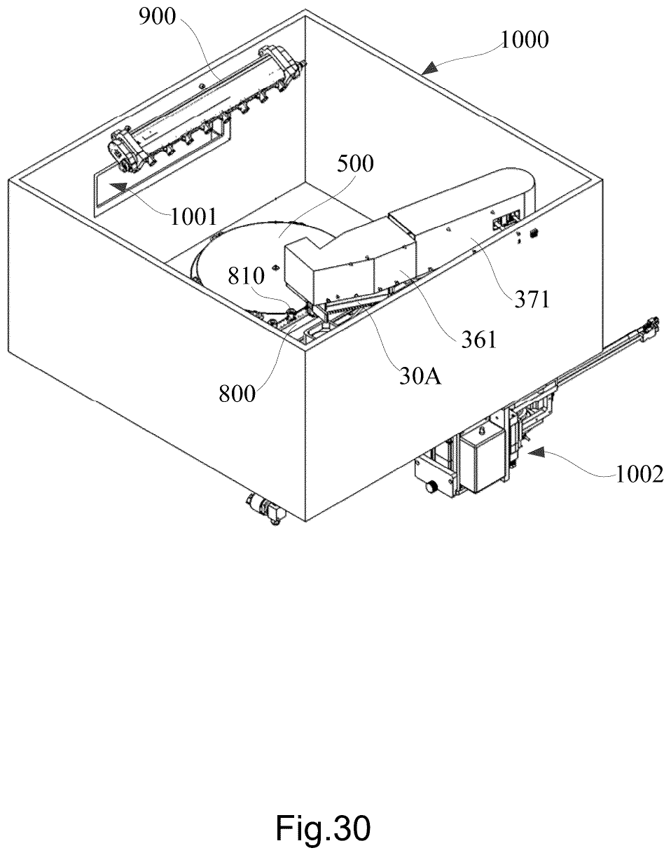

Referring to FIGS. 29 and 30, this embodiment provides a substrate processing apparatus comprising a chamber 1000, a substrate tray 400, a cleaning device 10A, and a megasonic emission device 30A. The substrate tray 400, the cleaning device 10A, and the megasonic emission device 30A are provided in the chamber 1000. The substrate tray 400 is used to carry a substrate 500, and the cleaning device 10A is used to clean the megasonic emission device 30A. The cleaning device 10A may be an existing cleaning device, or the cleaning device 10 in embodiment 1 may be used.

The substrate processing apparatus further comprises a first ion rod 800 and a second ion rod 900. The first ion rod 800—is disposed in the chamber 1000 between the substrate tray 400 and the cleaning device 10A, with the outlet 810 of the first ion rod 800 facing upward. During movement of the megasonic emission device 30A from the substrate tray 400 to the cleaning device 10A, or from the cleaning device 10A to the substrate tray 400, the bottom of the megasonic emission device 30A passes downwardly through the first ion rod 800. The first ion rod 800 blows ionic wind through the outlet 810 toward the above megasonic emission device 30A to neutralize the charges on the megasonic emission device 30A and prevent these charges from being carried to the surface of the substrate 500 to cause a discharge phenomenon. In addition, when the megasonic emission device 30A is parked at any position within the ion wind-coverable area of the first ion rod 800, the first ion rod 800 may blow ion wind to the megasonic emission device 30A to neutralize the charges on the megasonic emission device 30A, thereby realizing the purpose of removing static electricity.

The second ion rod 900 is also provided in the chamber 1000, and the second ion rod 900 is located in the upper side of the window 1001. The substrate 500 is put into the chamber 1000 or taken out from the chamber 1000 through the window, and the substrate 500 is located in the ionized wind coverage area of the second ion rod 900 when the substrate 500 is placed on the substrate tray 400. The second ion rod 900 blows ionized wind to the substrate 500 from the exhaust 910, neutralizing the residual charges on the surface of the substrate 500.

### Fifth Embodiment

Embodiment 5 presents another embodiment for eliminating static electricity on the megasonic emission device 30A. A second ion rod 900 is used to neutralize the charges on the megasonic emission device 30A.

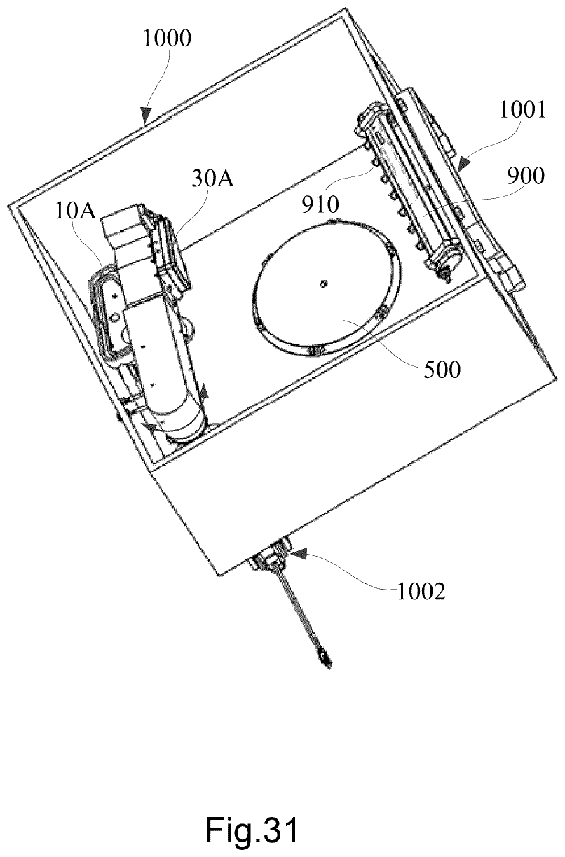

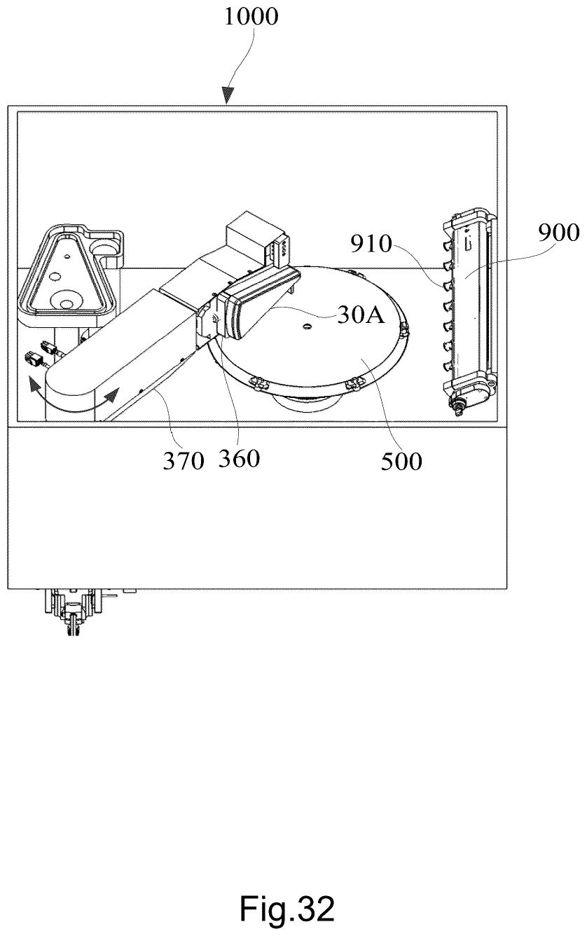

Referring to FIGS. 31 and 32, this embodiment provides a substrate processing apparatus comprising a second ion rod 900, a megasonic emission device 30A.

In the prior art, the second ion rod 900 is commonly used to neutralize the residual charges on the surface of the substrate 500. The working principle is to ionize the air and water vapor in the atmosphere to form positive and negative charges by pressurizing the silicon needles inside the ion rod, and then blow these positive and negative charges out of the exhaust 910 by using N2 to neutralize the residual charges on the surface of the substrate 500.

In this embodiment, the second ion rod 900 is provided on the inner sidewall of the chamber 1000, and a window 1001 (refer to the window 1001 shown in FIG. 30 of embodiment 4) is provided on the inner sidewall for the substrate 500 to get in and out, and the second ion rod 900 is located above the window 1001.

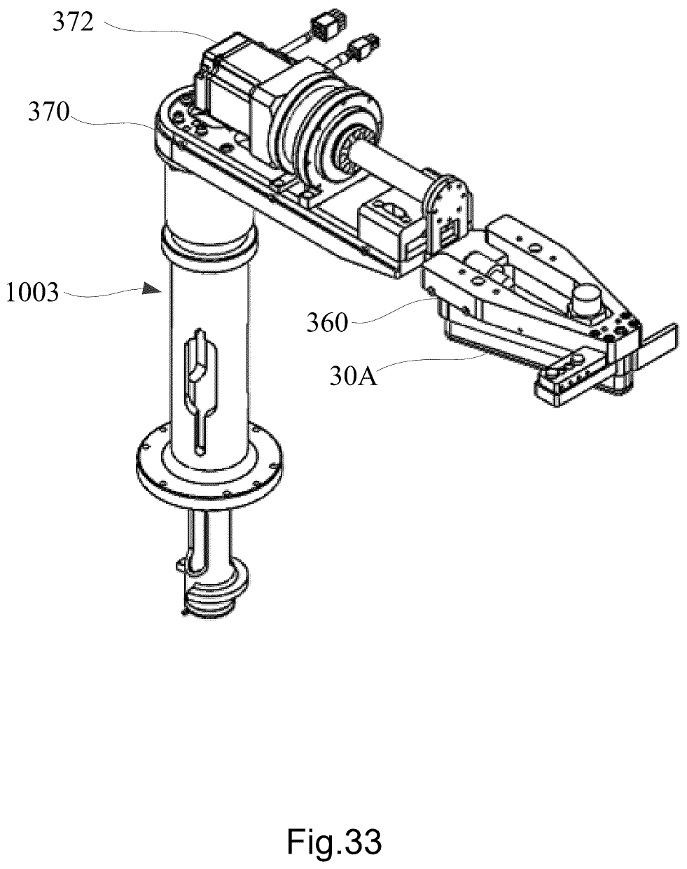

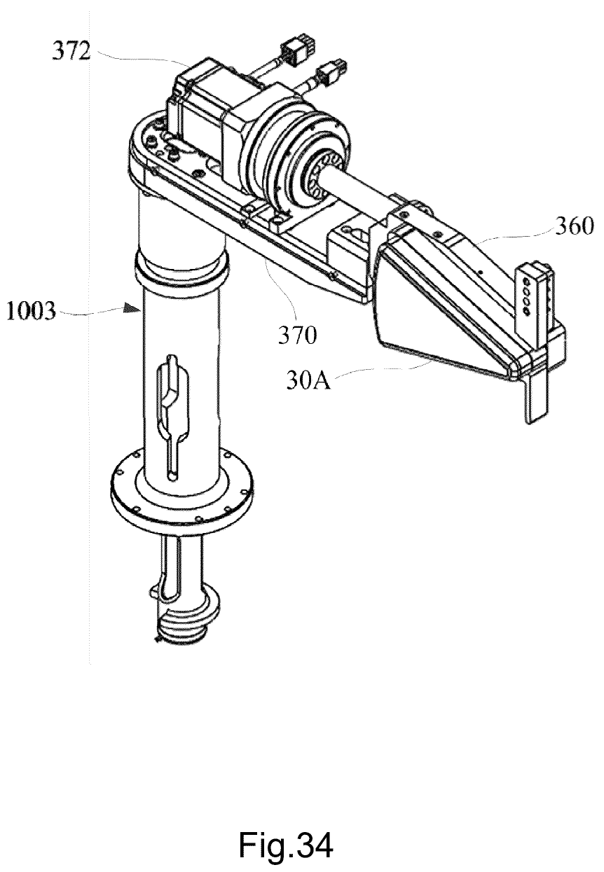

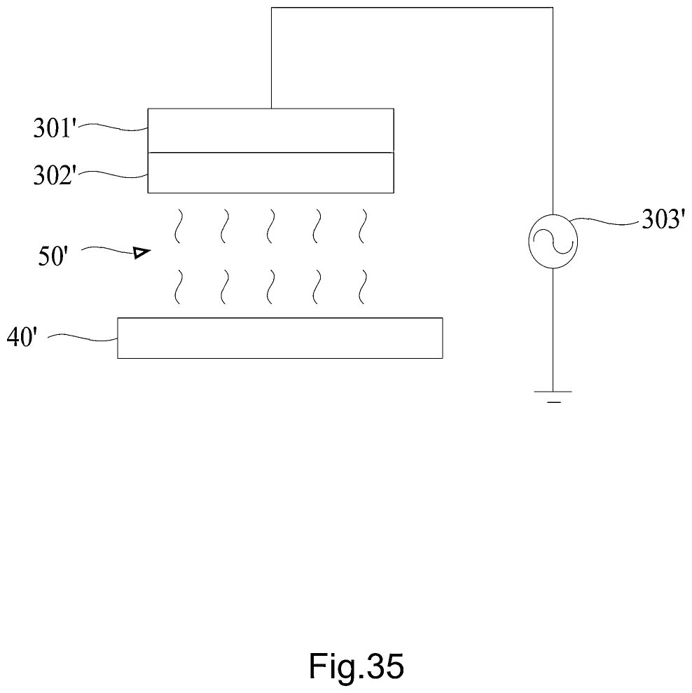

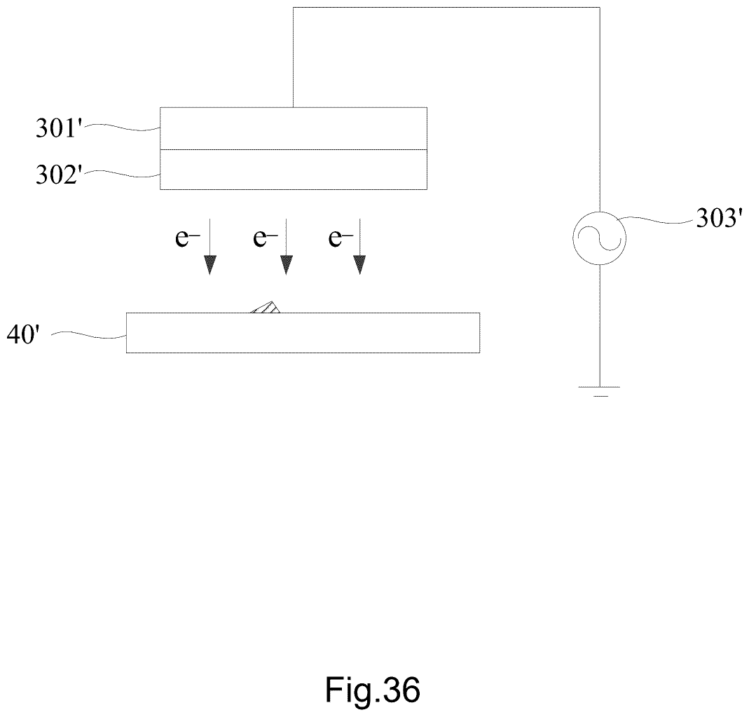

Referring to FIGS. 33 and 34, the substrate processing apparatus further comprises a first cantilever 360 and a second cantilever 370. The first cantilever 360 is installed on top of the megasonic emission device 30A. The second cantilever 370 is provided with a driving device 372, which rotates the megasonic emission device 30A by actuating the first cantilever 360, so as to rotate the megasonic emission apparatus 30A within the area that can be covered by ion wind of the second ion rod 900.

The actuator 1002 in the substrate processing apparatus drives the second cantilever 370 up or down and rotates the second cantilever 370 by means of the screw 1003. After the process of the megasonic emission device 30A is completed, the second cantilever 370 driven by the actuator 1002 connects the first cantilever 360 to raise the megasonic emission device 30A and move the megasonic emission device 30A to the ionizing wind-coverable area of the second ion rod 900 (as shown in FIG. 32 where the megasonic emission device 30A is located). And then the megasonic emission device 30A can be rotated by the driving device 372 on the second cantilever 370, causing the megasonic emission device 30A to rotate at any angle, so that the ionized wind of the second ion rod 900 through the exhaust 910 uniformly blow to all parts of the megasonic emission 30A, to achieve the purpose of removing the static electricity.

Finally, it should be noted that: the above embodiments are only used to illustrate the technical solutions of the present invention, not to limit it. Although the present invention is described in detail with reference to the foregoing embodiments, it should be understood by those of ordinary skill in the art that: It is still possible to modify the technical solutions recorded in the preceding embodiments or to make equivalent substitutions for some or all of the technical features therein. However, such modifications or substitutions do not take the essence of the corresponding technical solutions out of the scope of the technical solutions of the embodiments of the present invention.

1. A substrate processing apparatus, comprising:
a chamber;
a substrate tray, provided within the chamber, for carrying a substrate;
a megasonic emission device, for transmitting megasonic energy to chemical solution between the megasonic emission device and the substrate;
a cleaning device, for cleaning the megasonic emission device, the cleaning device comprising an electrostatic conductor assembly provided in the cleaning device and provided for electrically connecting with the megasonic emission device for conducting the charges away from the megasonic emission device.

2. The substrate processing apparatus according to claim 1, wherein the electrostatic conductor assembly is fixed to the bottom of the cleaning device, and the electrostatic conductor assembly is grounded;
when the megasonic emission device is cleaned in the cleaning device, the electrostatic conductor assembly is electrically connected to the megasonic emission device by means of the cleaning solution in the cleaning device, so as to cause charges on the megasonic emission device to be conducted away sequentially through the cleaning solution in the cleaning device and the electrostatic conductor assembly.

3. The substrate processing apparatus according to claim 2, wherein the electrostatic conductor assembly comprises a connection terminal and a wire, the connection terminal and the wire are electrically connected, the connection terminal is fixedly located at the bottom of the cleaning device, and the wire is grounded.

4. The substrate processing apparatus according to claim 3, wherein the first end of the connection terminal penetrates the bottom of the cleaning device and is electrically connected to the cleaning solution, and the second end of the connection terminal is connected to the wire.

5. The substrate processing apparatus according to claim 3, wherein the connection terminal runs through the bottom of the cleaning device, a cavity is provided within the connection terminal, and the wire is electrically connected to the cleaning solution through the cavity.

6. The substrate processing apparatus according to claim 4, wherein the electrostatic conductor assembly further comprises a shield covering the second end of the connection terminal, the shield is provided with a through-wire hole, and the wire is grounded after passing through the through-wire hole.

7. The substrate processing apparatus according to claim 1, further comprising:
a grounded electric conductor, configured such that when the megasonic emission device is located above the substrate, the charges on the megasonic emission device are conducted to the electric conductor through the chemical solution on the upper surface of the substrate and are conducted away by the electric conductor.

8. The substrate processing apparatus according to claim 7, wherein when the megasonic emission device is lowered above the substrate, the lower surface of the electric conductor contacts the chemical solution on the upper surface of the substrate prior to or at the same time as the lower surface of the megasonic emission device does, such that the charges on the megasonic emission device are conducted to the electric conductor by the chemical solution and are conducted away by the electric conductor.

9. The substrate processing apparatus according to claim 8, wherein the substrate processing apparatus further comprises a first cantilever installed on top of the megasonic emission device;
the electric conductor comprises an electrically conductive portion and a fixing portion connected, the electrically conductive portion is fixed to the first cantilever by the fixing portion, the electrically conductive portion is in contact with or spaced apart from at least one of the sidewalls of the megasonic emission device, and a lower surface of the electrically conductive portion exceeds the lower surface of the megasonic emission device.

10. The substrate processing apparatus according to claim 9, wherein the megasonic emission device has a triangular or pie shape, the megasonic emission device has a first sidewall, a second sidewall, and a third sidewall, and the conductive portion is provided in contact with or spaced apart from at least one of the first sidewall, second sidewall, and third sidewall of the megasonic emission device.

11. The substrate processing apparatus according to claim 7, wherein the electric conductor is made of ESD PTFE, ESD PEEK, ESD PCTFE, ESD ETFE or ESD PFA material.

12. The substrate processing apparatus according to claim 1, further comprising:
a grounded conductive nozzle, configured such that when the megasonic emission device is lowered above the substrate, the conductive nozzle first sprays the chemical solution onto the upper surface of the substrate, and when the megasonic emission device is immersed in the chemical solution film on the upper surface of the substrate, the charges on the megasonic emission device are conducted to the conductive nozzle through the chemical solution and are conducted away by the conductive nozzle.

13. The substrate processing apparatus according to claim 12, wherein the conductive nozzle is provided on one side of the megasonic emission device.

14. The substrate processing apparatus according to claim 12, wherein the conductive nozzle has an inlet port and a plurality of outlet ports, the inlet port is provided on top of the conductive nozzle, and the plurality of outlet ports are evenly distributed at the bottom of the conductive nozzle.

15. The substrate processing apparatus according to claim 12, wherein the conductive nozzle is made of ESD PTFE, ESD PEEK, ESD PCTFE, ESD ETFE or ESD PFA material.

16. The substrate processing apparatus according to claim 1, further comprising:
a first ion rod, provided within the chamber and disposed between the substrate tray and the cleaning device, the first ion rod having outlets facing upward such that when the megasonic emission device passes over the first ion rod in the course of movement between the substrate tray and the cleaning device, the first ion rod blowing ionic wind through the outlets toward the megasonic emission device above to neutralize charges on the megasonic emission device.

17. The substrate processing apparatus according to claim 1, further comprising:
a second ion rod, provided in an inner sidewall of the chamber;
a driving device, for driving the megasonic emission device to rotate such that the megasonic emission device rotates within the ionized wind-coverable area of the second ion rod.

18. The substrate processing apparatus according to claim 17, further comprising:
a first cantilever and a second cantilever, the first cantilever being installed on top of the megasonic emission device, the second cantilever being provided with the driving device, the driving device rotating the megasonic emission device by driving the first cantilever such that the megasonic emission device rotating within the ionized wind-coverable area of the second ion rod.

19.-28. (canceled)
